(19) United States
(12) Patent Application Publication
(10) Pub. No.: US 2023/0397481 A1
(43) Pub. Date: Dec. 7, 2023

(54) QUINOXALINE-BASED CONJUGATED POLYMER, CONTAINING CYANO GROUP, FOR POLYMER SOLAR CELL DONOR, AND POLYMER SOLAR CELL COMPRISING SAME

(71) Applicant: Pukyong National University Industry-University Cooperation Foundation, Busan (KR)

(72) Inventors: Joo Hyun KIM, Busan (KR); Jae Won CHANG, Busan (KR)

(73) Assignee: Pukyong National University Industry-University Cooperation Foundation, Busan (KR)

(21) Appl. No.: 18/044,917

(22) PCT Filed: Feb. 3, 2021
(86) PCT No.: PCT/KR2021/001425

§ 371 Date: Mar. 10, 2023

(30) Foreign Application Priority Data
Sep. 17, 2020 (KR) 10-2020-0119947

(51) Int. Cl. H10K 85/10; C08G 61/12

(52) U.S. Cl. CPC H10K 85/113; H10K 30/30; H10K 85/151; C08G 2261/3243; C08G 2261/145; C08G 2261/143; C08G 2261/91; C08G 2261/124; C08G 2261/149; C08G 2261/148; C08G 2261/18; C08G 2261/3241; C08G 2261/3223; C08G 2261/228; C08G 61/126

(57) ABSTRACT

The present invention relates to a conjugated polymer compound for a polymer solar cell donor and a polymer solar cell comprising same, wherein the conjugated polymer compound has a D-A form in which an electron-donating unit (benzodithiophene, BDT) and an electron-withdrawing unit (quinoxline, Qx) are combined, where a cyano (CN) substituent instead of fluorine (F) is introduced into the Qx unit to improve charge generation, charge transfer, and charge recombination characteristics of the polymer solar cell regardless of the type of acceptor contained in a photo-active layer, so that a polymer solar cell with greatly improved photo-conversion efficiency (PCE) can be implemented.

### TECHNICAL FIELD

The present invention relates to a conjugated polymer compound for a donor contained in a photoactive layer of a polymer solar cell and to a polymer solar cell including the same.

### BACKGROUND ART

Polymer solar cells (PSCs) are based on a bulk heterojunction (BHJ) structure formed by blending a conjugated electron donor and an electron acceptor and are fabricated through a solution process. Due to excellent properties, such as light weight, mechanical flexibility, and low-cost production in large-area, polymer solar cells have drawn great attention as electricity generation devices.

Typically, a p-type conjugated polymer donor contained in the photoactive layer formed of the bulk heterojunction structure includes an electron donor (D) and an electron acceptor (A), alternately, along a polymer backbone to reduce band gaps by promoting the creation of an intramolecular charge transfer (ICT) state.

Furthermore, incorporating a strong electron-withdrawing unit into a polymer structure with the formation of a D-A type architecture reduces the lowest unoccupied molecular orbital (LUMO) and the highest occupied molecular orbital (HOMO) energy levels of a polymer to improve the open-circuit voltage (VOC) and PCE of a device. As a result, the incorporation is considered one of the potential methods of approach in terms of improving PSC photovoltaic perfoLmance.

In particular, with the characteristics, such as small size, high electron affinity, and low steric hindrance, fluorine (F) atoms can be preferentially considered electron-withdrawing units to be introduced into D-A type polymers. Accordingly, there were several remarkable early studies to implement high-performance PSCs based on polymers containing a fluorine atom.

However, PSC photovoltaic performance is required to be further improved by introducing strong electron-withdrawing functional groups, other than fluorine, into p-type conjugated polymers.

### DISCLOSURE

### Technical Problem

An object of the present invention is to provide a novel quinoxaline-based conjugated polymer compound for a polymer solar cell donor, into which a cyano group (—CN) is introduced as an electron-withdrawing unit, and a polymer solar cell including the same.

### Technical Solution

The present invention provides a conjugated polymer compound for a polymer solar cell donor, the polymer compound represented by Formula 1 below.

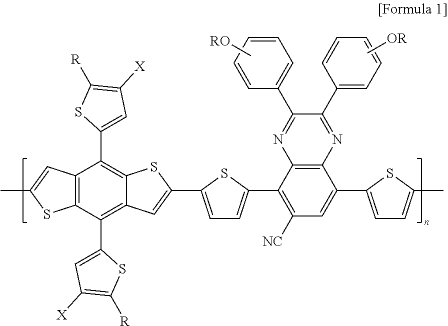

(In Formula 1,

n is an integer of 2 or more,

R is a substituted or unsubstituted alkyl having 2 to 10 carbon atoms, and

X is H or F.)

In addition, the conjugated polymer compound for the polymer solar cell donor represented by Formula 2 is provided:

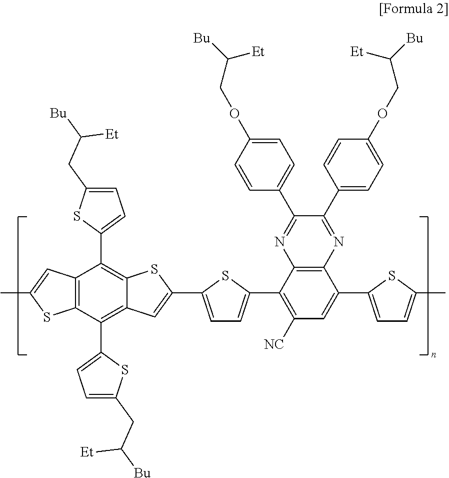

In addition, the conjugated polymer compound for the polymer solar cell donor represented by Formula 3 is provided:

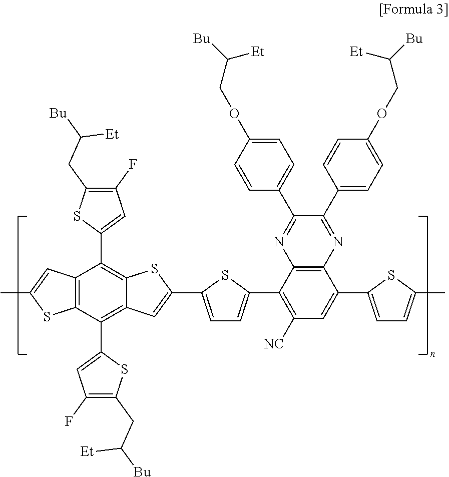

In addition, the conjugated polymer compound for the polymer solar cell donor represented by Formula 4 is provided:

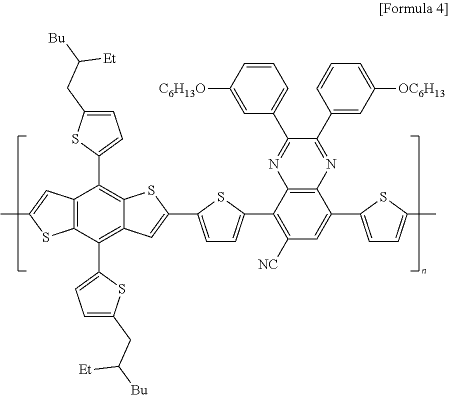

In addition, in another aspect of the present invention, the present invention provides a polymer solar cell having a photoactive layer containing the conjugated polymer compound as a donor.

In this case, a stacking structure of the polymer solar cell and a material of each layer, according to the present invention, are not particularly limited.

For example, the polymer solar cell, according to the present invention, may be an inverted polymer solar cell (iPSC) including: a negative electrode positioned on a transparent substrate; a photoactive layer containing an electron acceptor and an electron donor made of the conjugated polymer compound; and a positive electrode.

The substrate may be made of a transparent material with high light transmittance. Examples of the substrate may include glass, polycarbonate, polymethyl methacrylate, polyethylene terephthalate, polyamide, polyethersulfone, and the like.

In addition, the photoactive layer may be one in which a mixture including the electron acceptor and the electron donor, made of the conjugated polymer compound, is formed in a heterojunction structure. In this case, a fullerene derivative with high electron affinity, such as C60, C70, C76, C78, C82, C90, C94, C96, C720, C860, and the like may be used as the electron acceptor. Furthermore, non-fullerene-based acceptor, such as 2,2′-((2Z,2′Z)-((12,13-bis(2-butyloctyl)-12,13-dihydro-[1,2,5]thiadiazolo[3,4-e]thieno[2″,3″:4′,5′]thieno[2′,3′:4,5]pyrrolo[3,2-g]thieno[2′,3′:4,5]thieno[3,2-b]indole-2,10-diyl)bis(methanylylidene))bis(5,6-difluoro-3-oxo-2,3-dihydro-1H-indene-2,1- diylidene))dimalononitrile (Y6BO) and the like may be used as the electron acceptor.

Metal oxides, such as indium tin oxide (ITO), SnO₂, In₂O₃—ZnO (IZO), aluminum-doped ZnO (AZO), and gallium-doped ZnO (GZO), aluminum (Al), transition metals, such as silver (Ag), gold (Au), and platinum (Pt), rare earth metals, and semimetals, such as selenium (Se), may be used as the positive electrode and the negative electrode. Preferably, the positive electrode and the negative electrode are formed in consideration of a work function.

Specific examples of the polymer solar cell, according to the present invention, may include a polymer solar cell in which an ITO substrate, the photoactive layer including the electron donor made of the conjugated polymer compound and the electron acceptor made of [6,6]-Phenyl C71 butyric acid methyl ester (PC₇₁BM) or Y6BO, a metal oxide layer containing molybdenum oxide (MoO₃), and a silver (Ag) electrode layer are sequentially stacked. In this case, a zinc oxide (ZnO) layer may be further included between the ITO substrate and the photoactive layer.

### Advantageous Effects

According to the present invention, a conjugated polymer for a polymer solar cell donor is provided in a D-A form in which an electron-donating unit (benzodithiophene, BDT) and an electron withdrawing-unit (quinoxaline, Qx) are combined, while a cyano (CN) substituent is introduced into the Qx unit instead of fluorine (F) to improve charge generation, charge transfer, and charge recombination properties of a polymer solar cell, regardless of types of acceptor contained in a photoactive layer. As a result, the polymer solar cell with greatly improved photoelectric conversion efficiency (PCE) can be implemented.

Furthermore, when the conjugated polymer for the donor containing the CN group in the Qx unit further includes two fluorine (F) atoms in a thiophene side chain of the BDT unit, photovoltaic performance is further improved. Therefore, the polymer solar cell exhibiting a significantly high photo-conversion efficiency of up to 14% can be implemented.

### DESCRIPTION OF DRAWINGS

FIG. 1A is a diagram showing chemical structures of conjugated polymers for a donor prepared in Example of the present invention and chemical structures of acceptors used for synthesis of a photoactive layer, and FIG. 1B is a diagram illustrating a structure of an inverted PSC device prepared in Example of the present invention;

FIGS. 2A and 2B are diagrams showing synthesis pathways of PTB-FQx, PTB-CNQx, PTBF-CNQx, and PTB-CNQx-mH synthesized in Example of the present invention;

FIG. 3 is a diagram showing theLmogravimetric analysis (TGA) results for PTB-FQx, PTB-CNQx, and PTBF-CNQx;

FIG. 4 is a diagram showing UV-Vis spectra of PTB-FQx, PTB-CNQx, and PTBF-CNQx films;

FIG. 5 is a diagram showing a cyclic voltammetry (CV) curve of PTB-FQx, PTB-CNQx, and PTBF-CNQx;

FIGS. 6A to 6C are diagrams showing theoretical calculation results for dimer model units of PTB-FQx, PTB-CNQx, and PTBF-CNQx, respectively, at B3LYP/6-31** level based on density-functional theory (DFT);

FIGS. 7A and 7B are diagrams showing a J-V curve and an ICPE curve, respectively, of a PC₇₁BM acceptor-based PSC under optimal conditions, and FIGS. 7C and 7D are diagrams showing a J-V curve and an ICPE curve, respectively, of a Y6BO acceptor-based PSC under optimal conditions;

FIG. 8 is a diagram showing PL spectra of polymer films synthesized in Example and blend films containing each polymer and a Y6BO acceptor;

FIGS. 9A and 9B are diagrams showing J-V curves of a hole-only device and an electron-only device, respectively, based on PC₇₁BM and each polymer synthesized in Example, and FIGS. 9C and 9D are diagrams showing J-V curves of a hole-only device and an electron-only device, respectively, based on Y6BO and each polymer synthesized in Examples;

FIGS. 10A and 10B are diagrams showing a J_{Ph}-V_{eff} curve and a curve for V_{OC} versus light intensity of a PC₇₁BM-containing device, respectively, and FIGS. 10C and 10D are diagrams showing a J_{Ph}-V_{eff} curve and a curve for V_{OC} versus light intensity of a Y6BO-containing device, respectively;

FIGS. 11A and 11B are diagrams of graphs showing relations between J_{SC} and light intensity in a PC₇₁BM-containing PSC and a Y6BO-containing PSC, respectively;

FIGS. 12A to 12C are diagrams of GIWAXS images of polymer films synthesized in Example of the present invention, FIGS. 12D to 12F are diagrams of GIWAXS images of blend films containing PC₇₁BM and each polymer synthesized in Example of the present invention, FIGS. 12G to 12I are diagrams of GIWAXS images of blend films containing Y6BO and each polymer synthesized in Example of the present invention, FIG. 12K is a diagram of a line-cut profile curve corresponding to in-plane (IP) and out-of-plane (OOP) directions of each polymer film synthesized in Example of the present invention, FIG. 12L is a diagram of a line-cut profile curve corresponding to in-plane (IP) and out-of-plane (OOP) directions of blend films containing PC₇₁BM and each polymer synthesized in Example of the present invention, and FIG. 12M is a diagram of a line-cut profile curve corresponding to in-plane (IP) and out-of-plane (OOP) directions of blend films containing Y6BO and each polymer synthesized in Example of the present invention;

FIG. 13A is a diagram of a GIWAX image of Y6BO film, and FIG. 13B is a diagram of a graph showing a line-cut profile curve corresponding to in-plane (IP) and out-of-plane directions; and

FIGS. 14A to 14C are diagrams of TEM images for active layers of blend films based on PC₇₁BM and each polymer synthesized in Example of the present invention, and FIGS. 14D to 14F are diagrams of TEM images for active layers of blend films based on Y6BO and each polymer synthesized in Example of the present invention.

### BEST MODE

In the following description of the present invention, a detailed description of known functions and configurations incorporated herein will be omitted when it may make the subject matter of the present disclosure unclear.

The embodiments according to the concept of the present invention can be variously modified and can take various forms, so that the embodiments are illustrated in the drawings and described in detail herein. It should be understood, however, that the embodiments according to the concepts of the present invention are not limited to the specific foinas disclosed, but include modifications, equivalents, or alternatives falling within the spirit and scope of the present invention.

The terms used herein are used for explaining a specific exemplary embodiment, not limiting the present inventive concept. Thus, the expression of singularity herein includes the expression of plurality unless clearly specified otherwise in context. The terms such as “include” or “comprise” used herein may be construed to denote a certain characteristic, number, step, operation, constituent element, or a combination thereof, but may not be construed to exclude the existence of or a possibility of addition of one or more other characteristics, numbers, steps, operations, constituent elements, or combinations thereof.

In addition, unless otherwise specified, the following terms and phrases used herein have the following meanings.

“Alkyl” is a hydrocarbon having normal, secondary, tertiary or cyclic carbon atoms. For example, an alkyl group may have 1 to 20 carbon atoms (i.e., C₁-C₂₀ alkyl), 1 to 10 carbon atoms (i.e., C₁-C₁₀ alkyl), or 1 to 6 carbon atoms (i.e., C₁-C₆ alkyl). Examples of suitable alkyl groups include methyl (Me, —CH₃), ethyl (Et, —CH₂CH₃), 1-propyl (n-Pr, n-propyl, —CH₂CH₂CH₃), 2-propyl (i-Pr, i-propyl, —CH(CH₃)₂), 1-butyl (n-Bu, n-butyl, —CH₂CH₂CH₂CH₃), 2-methyl-1-propyl (i-Bu, i-butyl, —CH₂CH(CH₃)₂), 2-butyl (s-Bu, s-butyl, —CH(CH₃)CH₂CH₃), 2-methyl-2-propyl (t-Bu, t-butyl, —C(CH₃)₃), 1-pentyl (n-pentyl, —CH₂CH₂CH₂CH₂CH₃), 2-pentyl (—CH(CH₃)CH₂CH₂CH₃), 3-pentyl (—CH(CH₂CH₃)₂), 2-methyl-2-butyl (—C (CH₃)₂CH₂CH₃), 3-methyl-2-butyl (—CH(CH₃)CH(CH₃)₂), 3-methyl-1-butyl (—CH₂CH₂CH(CH₃)₂), 2-methyl-1-butyl (—CH₂CH(CH₃)CH₂CH₃), 1-hexyl (—CH₂CH₂CH₂CH₂CH₂CH₃), 2-hexyl (—CH(CH₃)CH₂CH₂CH₂CH₃), 3-hexyl (—CH(CH₂CH₃)(CH₂CH₂CH₃)), 2-methyl-2-pentyl (—C(CH₃)₂CH₂CH₂CH₃), 3-methyl-2-pentyl (—CH(CH₃)CH(CH₃)CH₂CH₃), 4-methyl-2-pentyl (—CH(CH₃)CH₂CH(CH₃)₂), 3-methyl-3-pentyl (—C (CH₃) (CH₂CH₃)₂), 2-methyl-3-pentyl (—CH(CH₂CH₃)CH(CH₃)₂), 2,3-dimethyl-2-butyl (—C(CH₃)₂CH(CH₃)₂), 3,3-dimethyl-2-butyl (—CH(CH₃)C(CH₃)₃, and octyl (—(CH₂)₇CH₃). Examples of the alkyl group are not limited thereto.

The term “substituted” regarding alkyl and the like, for example, “substituted alkyl” and the like, means alkyl and the like in which one or more hydrogen atoms are each independently substituted with a non-hydrogen substituent. Typical substituents include —X, —R, —O⁻, ═O, —OR, —SR, —S⁻, —NR₂, —N⁺R₃, ═NR, —CX₃, —CN, —OCN, —SCN, —N═C═O, —NCS, —NO, —NO₂, ═N₂, —N₃, —NHC(═O)R, —C(═O)R, —C(═O)NRR, —S(═O)₂O⁻, —S(═o)₂OH, —S(═O)₂R, —OS(═O)₂OR, —S(═O)₂NR, —S(═O)R, —OP(═O)(OR)₂, —N(═O)(OR)₂, —N(═O)(O⁻₂, —N(═O)(OH)₂, —N(O)(OR)(O⁻), —C(═O)R, —C(═O)X, —C(S)R, —C(O)OR, —O(O)O⁻, —O(O)O⁻, C(O)SR, —C(S)SR, —C(O)NRR, —C(S)NRR, and —C(═NR)NRR (where X is each independently a halogen: F, Cl, Br, or I, and R is each independently H, alkyl, aryl, arylalkyl, heterocycle, a protecting group, or a prodrug moiety). Examples of the substituent are not limited thereto.

Hereinafter, the present invention will be described in detail with Example.

### EXAMPLE

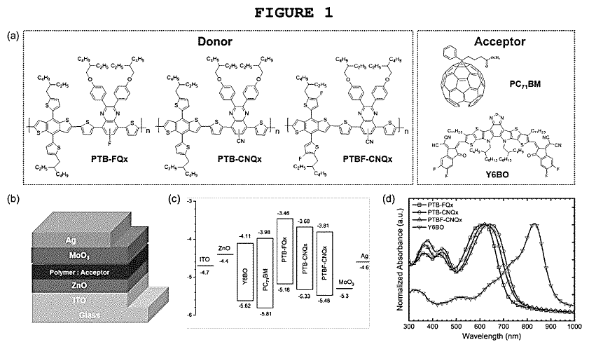

In Example, three quinoxaline (Qx)-based conjugated polymers (PTB-FQx, PTB-CNQx, and PTBF-CNQx) with a typical D-A arrangement were synthesized (see FIG. 1A). Then, structural, optical, and electrochemical properties of the conjugated polymers were examined. Next, an inverted fullerene PSC in which ITO, ZnO, the conjugated polymer and an acceptor, MoO₃, and Ag were sequentially stacked and a non-fullerene PSC were fabricated to examine overall photovoltaic properties of the conjugated polymers (see FIG. 1B).

1. Synthesis of Quinoxaline-Based Conjugated Polymers (PTB-FQx, PTB-CNQx, PTBF-CNQx, and PTB-CNQx-mH)

(1) Synthesis of PTB-FQx, PTB-CNQx, and PTBF-CNQx

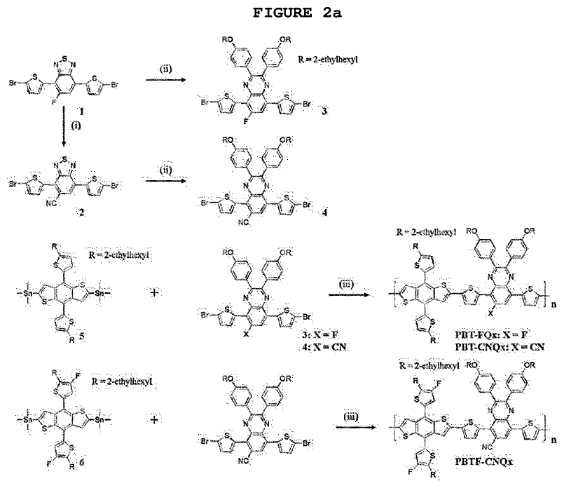

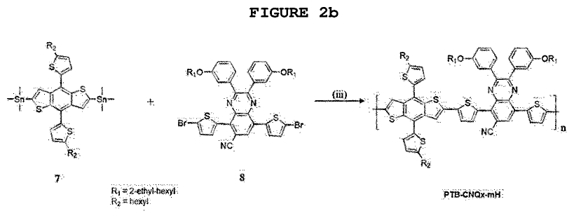

As shown in FIG. 2A, 7-bis(5-bromothiophen-2-yl)-5-fluorobenzo[c][1,2,5]thiadiazole (1) and 1,2-bis(4-((2-ethylhexyl)oxy)phenyl)ethane-1,2-dione were first synthesized according to an early reported method (J. Kim et al., ACS applied materials & interfaces 2014, 6, 7523; Y. H. Tseng et al., Journal of Polymer Science Part A: Polymer Chemistry 2005, 43, 5147) to synthesize corresponding conjugated polymers.

Then, an existing fluorine atom in (1) was substituted with a CN group to synthesize 4,7-bis(5-bromothiophen-2-yl)benzo[c][1,2,5]thiadiazole-5-carbonitrile (2).

An F substituent-containing dibrominated Qx monomer (3) and a CN substituent-containing dibrominated Qx monomer (4) were synthesized through reactions of 1,2-bis(4-((2-ethylhexyl)oxy)phenyl)ethane-1,2-dione with benzothiadiazole derivatives of (1) and (2), respectively, under successive Zn-involved reduction and condensation reaction conditions.

A BDT monomer (4,8-bis(5-(2-ethylhexyl)thiophene-2-yl)benzo[1,2-b:4,5-b′]dithiophene-2,6-diyl)bis(trimethylstannane) (5) underwent Stille polymerization with the F substituent-containing dibrominated Qx monomer (3) and the CN substituent-containing dibrominated Qx monomer (4) to obtain D-A type polymers, PTB-FQx and PTB-CNQx, respectively.

Lastly, under the same conditions, PTBF-CNQx was synthesized through polymerization between a fluorinated BDT monomer (4,8-bis(5-(2-ethylhexyl)-4-fluorothiophen-2-yl)benzo-[1,2-b:4,5-by]dithiophene-2,6-diyl)bis(trimethylstannane) (6) and the Qx monomer (4).

1) Synthesis of 4,7-bis(5-bromothiophen-2-yl)benzo[c][1,2,5]thiadiazole-5-carbonitrile (Compound 2)

4,7-bis(5-bromothiophen-2-yl)-5-fluorobenzo[c][1,2,5]thiadiazole (Compound 1, 0.66 mmol), KCN (0.85 mmol), and 18-crown-6 (0.085 mmol) were added to a round-bottom flask and dissolved in a mixed solvent of anhydrous THF (20 mL) and DMF (5 mL). Then, the resulting solution was bubbled with nitrogen, and the mixed solution was refluxed at a temperature of 65° C. for 48 hours under an N₂ atmosphere. THF was evaporated under reduced pressure, and the residue was dissolved in dichloromethane (MC) and washed with water three times. An ammonia solution was added to a water phase to eliminate the remaining cyanides, and an organic phase was dried with magnesium sulfate (MgSO₄) and then filtered. The solvent in the solution was removed using a rotary vacuum evaporator. A crude product was further purified via recrystallization using methanol and chloroform.

Yield: 78% (red powder). ¹H NMR (600 MHz, CDCl3): δ (ppm)=7.98 (d, 1H, J =4.02 Hz), 7.96 (s, 1H), 7.83 (d, 1H, J=4.02 Hz), 7.25 (d, 1H, J=4.02 Hz), 7.20 (d, 1H, J=4.02 Hz). ¹³C NMR (150 MHz, CDCl3): δ (ppm)=152.6, 152.5, 138.4, 135.9, 131.3, 131.0, 130.5, 129.7, 128.5, 126.9, 126.1, 119.5, 118.5, 116.8, 108.5. MALDT-TOF MS: m/z calcd, 482.799; found, 482.942 [M⁺]

2) Synthesis of 5,8-bis(5-bromothiophen-2-yl)-2,3-bis(4-((2-ethylhexyl)oxy)phenyl)-6-fluoroquinoxaline (Compound 3)

4,7-bis(5-bromothiophen-2-yl)-5-fluorobenzo[c][1,2,5]thiadiazole (Compound 1, 1 mmol) and Zn powder (20 mmol) were added to a 30 mL of acetic acid solution, and then stirred for 6 hours until the color changed to white. The mixed solution was directly filtered after reactions were completed to remove the zinc powder. Then, 1,2-bis(4-((2-ethylhexyl)oxy)phenyl)ethane-1,2-dione (1 mmol) was rapidly added to the filtrate and stirred overnight at a reflux temperature. Next, the mixed solution was cooled to room temperature, poured into water, and extracted with ethyl acetate. An organic phase was separated and dried with magnesium sulfate (MgSO₄). A rotary vacuum evaporator was used to remove the solvent, and a crude product was then purified by column chromatography using a solution of dichloromethane and hexane (1:7 (v/v)) as an eluent.

Yield=43% (yellow-orange solid). ¹H NMR (600 MHz, CDCl3): δ (ppm)=7.88 (d, 1H, J=13.56 Hz), 7.77 (d, 1H, J=3.54 Hz), 7.68 (dd, 4H, J=11.10, 8.58 Hz), 7.55 (d, 1H, J=4.02 Hz), 7.16 (d, 1H, J=4.02 Hz), 7.14 (d, 1H, J=4.02 Hz), 6.94 (dd, 4H, J=8.58, 3.00 Hz), 3.93-3.89 (m, 4H), 1.78-1.74 (m, 2H), 1.53-1.39 (m, 8H), 1.35-1.33 (m, 8H), 0.97-0.91 (m, 12H). ¹³C NMR (150 MHz, CDCl3): δ (ppm)=160.3, 160.2, 159.1, 157.4, 151.7, 150.4, 137.9, 137.2, 137.1, 133.5, 133.1, 132.0, 131.8, 130.4, 130.3, 130.1, 130.0, 129.9, 129.8, 128.8, 128.7, 125.5, 118.1, 117.5, 115.6, 115.5, 114.6, 114.4, 114.1, 70.5, 39.4, 30.4, 29.1, 23.8, 23.1, 14.1, 11.2. MALDI-TOF MS: m/z calcd, 878.793; found, 879.308 [M⁺].

3) Synthesis of 5,8-bis(5-bromothiophen-2-yl)-2,3-bis(4-((2-ethylhexyl)oxy)phenyl)quinoxaline-6-carbonitrile (Compound 4)

Compound 4 was synthesized through a synthetic procedure similar to that of Compound 3 above. 4,7-bis(5-bromothiophen-2-yl)benzo[c][1,2,5]thiadiazole-5-carbonitrile (2, 0.42 mmol) and 1,2-bis(4-((2-ethylhexyl)oxy)phenyl)ethane-1,2-dione (0.42 mmol) were used as reactants, and a ratio of dichloromethane to hexane contained in an eluent for column chromatography was 1:7 (v/v).

Yield=73% (orange solid). ¹H NMR (600 MHz, CDCl3): δ (ppm) 8.22 (s, 1H), 7.87 (d, 1H, J=4.02 Hz), 7.72 (d, 2H, J=8.58 Hz), 7.66 (d, 2H, J=8.58 Hz), 7.58 (d, 1H, J=4.02 Hz), 7.21 (d, 1H, J=4.02 Hz), 7.17 (d, 1H, J=4.08 Hz), 6.96-6.92 (m, 4H), 3.92-3.89 (m, 4H), 1.78-1.73 (m, 2H), 1.52-1.40 (m, 8H), 1.35-1.33 (m, 8H), 0.97-0.91 (m, 12H). ¹³C NMR (150 MHz, CDCl3): 161.0, 160.8, 153.3, 152.8, 137.3, 137.2, 136.4, 135.3, 133.7, 132.0, 131.9, 130.7, 130.2, 129.6, 129.5, 129.2, 129.1, 127.8, 126.1, 120.0, 119.2, 118.5, 114.4, 114.3, 108.5, 70.6, 70.5, 39.3, 30.5, 29.1, 23.8, 23.0, 14.1, 11.1. MALDI-TOF MS: m/z calcd 885.818; found, 886.189 [M⁺].

4) Synthesis of D-A type Polymer by Stille Coupling Reaction

In a Schlenk flask, a BDT monomer (Compound 5 or 6), a dibrominated DPQ monomer (Compound 3 or 4), and Pd(PPh₃)₄ (3% mol) were mixed in degassed toluene. The mixed solution was bubbled with nitrogen for 15 minutes and stirred at a temperature of 90° C. for 48 days under an N₂ atmosphere. Polymerization was completed by adding two end-capping agents (2-trimethylstannylthiophene and 2-bromothiophene) at 2-hour intervals. Thereafter, the polymer solution was precipitated in methanol, and the solid polymer was collected by filtration. Soxhlet extraction using methanol, acetone, hexane and chloroform was continuously performed to purify the polymer. A chloroform fraction was concentrated, and the polymer was then precipitated again in methanol. Lastly, the solid polymer was dried in vacuo at a temperature of 50° C.

i) PTB-FQx

4,8-bis(5-(2-ethylhexyl)thiophen-2-yl)benzo[1,2-b:4,5-b′]dithiophene-2,6-diyl)bis(trimethylstannane) (Compound 5, mmol) and a dibrominated DPQ monomer (Compound 3, 0.2 mmol) were used as reactants.

Yield: 92% (deep blue solid). ¹H NMR (600 MHz, CDCl3): δ (ppm)=8.04-7.45 (br, 7H), 7.45-7.35 (br, 2H), 7.22-7.01 (br, 4H), 7.01-6.60 (6H), 4.31-3.78 (br, 4H), 3.20-2.80 (br, 4H), 2.27-1.99 (br, 4H), 1.52-1.40 (br, 16H), 1.40-1.25 (br, 16H), 1.10-0.90 (br. 24H). Molecular weight by GPC: number-average molecular weight (Mn)=38.40 KDa, polydispersity index (PDI)=3.90. Elemental analysis: calcd (%) for C₇₈H₈₇FN₂O₂S₆: C 72.29, H 6.77, N 2.16, S 14.85; found: C 71.83, H 6.61, N 2.07, S 13.14.

ii) PTB-CNQx

4,8-bis(5-(2-ethylhexyl)thiophen-2-yl)benzo[1,2-b:4,5-b′]dithiophene-2,6-diyl)bis(trimethylstannane) (Compound 5, 0.2 mmol) and a dibrominated DPQ monomer (Compound 3, 0.2 mmol) were used as reactants.

Yield=88% (deep green solid). ¹H NMR (600 MHz, CDCl3): (ppm)=7.91-7.56 (br, 7H), 7.44-7.30 (br, 2H), 7.14-7.02 (br, 4H), 6.98-6.78 (br, 6H), 4.26-3.65 (br, 4H), 3.15-2.74 (br, 4H), 1.89-1.79 (br, 4H), 1.45-1.36 (br, 16H), 1.32-1.18 (br, 16H), 1.01-0.87 (br, 24H). Molecular weight by GPC: number-average molecular weight (Mn)=59.89 KDa, polydispersity index (PDI)=3.02. Elemental analysis: calcd (%) for C79H₈₇N₃O₂S₆: C 72.82, H 6.73, N 3.23, S 14.77; found: C 72.19, H 6.82, N 2.91, S 14.97.

iii) PTBF-CNQx

(4,8-bis(5-(2-ethylhexyl)-4-fluorothiophen-2-yl)benzo-[1,2-b:4,5-b′]dithiophene-2,6-diyl)bis(trimethylstannane) (Compound 6, 0.17 mol) and a dibrominated DPQ monomer (Compound 4, 0.17 mmol) were used as reactants. The synthesized polymer was dissolved in a chlorobenzene fraction.

Yield=84% (deep green solid). ¹H NMR (600 MHz, CDCl3): (ppm)=7.90-7.83 (br, 3H), 7.81-7.71 (br, 3H), 7.47-7.35 (br, 6H), 6.98-6.88 (br, 5H), 4.03-3.82 (br, 4H), 3.00-2.78 (br, 4H), 1.51-1.45 (br, 9H), 1.45-1.35 (br, 19H), 1.09-0.91 (br, 32H). Molecular weight by GPC: numberaverage molecular weight (Mn)=26.07 KDa, polydispersity index (PDI)=3.20 Elemental analysis: calcd (%) for C₇₉H₈₅F₂N₃O₂S₆: C 70.76, H 6.54, N 3.13, S 14.35; found: C 69.64, H 6.66, N 3.09, S 15.61.

(2) Synthesis of PTB-CNQx-mH

As shown in FIG. 2B, a mixture of 4,8-bis(5-(2-ethylhexyl)-4-fluorothiophen-2-yl)benzo[1,2-b:4,5-b′]dithiophene-2,6-diyl)bis(trimethylstannane) (Compound 7, 0.20 mmol) as a BDT monomer, a dibrominated DPQ monomer (Compound 8, 0.20 mmol), and Pd(PPh₃)₄ (3% mol) was dissolved in 10 ml of toluene for 15 minutes under nitrogen bubbling. Then the mixed solution was stirred at a temperature of 90° C. for 48 days under an N₂ atmosphere. Polymerization was completed by adding two end-capping agents (2-trimethylstannylthiophene and 2-bromothiophene) at 2-hour intervals. Thereafter, the polymer solution was precipitated in methanol, and a solid polymer was filtered. Soxhlet extraction using methanol, acetone, hexane, and chloroform was continuously performed to purify the polymer. The polymer was fully dissolved in chloroform, and a solvent was partially removed in vacuo to precipitate a concentrated polymer in methanol again. Lastly, the purified solid polymer was filtered and then dried in vacuo overnight at a temperature of 50° C.

Yield=93.6% (deep green solid). ¹H-NMR (400 MHz, CDCl 3) δ 7.50 (s, 2H), 7.39 (s, 2H), 7.35 (s, 1H), 7.31 (s, 1H), 7.28 (s, 2H), 7.20 (s, 4H), 7.10 (d, J=5.0 Hz, 3H), 6.98 (s, 3H), 6.87 (t, J=5.0 Hz, 1H), 3.43 (d, J=5.0 Hz, 4H), 2.69 (d, J=6.9 Hz, 4H), 2.14 (s, 4H), 1.68 (s, 2H), 1.57 (s, 8H), 1.49 (s, 6H), 1.27-1.23 (m, 22H), 0.90-0.84 (m, 10H). Molecular weight by GPC: number-average molecular weight (Mn)=18.22 KDa, polydispersity index (PDI)=3.43. Elemental analysis: calcd (%) for C₇₅H₇₇F₂N₃O₂S6: C 70.11, H 6.20, N 3.27, S 14.97; found: C 69.58, H 6.21, N 3.16, S 16.86.

2. Fabrication of Polymer Solar Cell (PSC) Containing PTB-FQx, PTB-CNQx, or PTBF-CNQx

To fabricate an inverted polymer solar cell in which ITO, ZnO, an active layer (conjugated polymer donor prepared in Example and PC₇₁BM), MoO₃, and Ag were sequentially stacked, a 25-nm-thick ZnO film was first deposited on an ITO surface using a sol-gel process. A ZnO film, which was partially crystalline, was prepared by heat curing of a pre-deposited ZnO precursor at a temperature of 200° C. for 10 minutes. The ZnO precursor solution was prepared by dissolving zinc acetate dehydrate (0.164 g) and ethanolamine (0.05 mL) in methoxyethanol (1 mL) and stirring the mixture for 30 minutes before film deposition. The active layer was prepared using a solution in which a polymer donor and chlorobenzene of the PC₇₁BM acceptor (containing 3.0 vol. % of 1,8-diiodooctane as a process additive) were mixed by spin-coating. Before the spin-coating, the mixed solution was filtered through a 0.2-μm polytetrafluoroethylene membrane filter. Lastly, a 20-nm-thick MoO₃ layer and a 100-nm-thick Ag layer were sequentially deposited by thermal evaporation at 2×10⁻⁶ Torr through a shadow mask with a device area of 0.09 cm². The J-V characteristics of a device were analyzed using KEITHLEY Model 2400 source-measure unit under AM 1.5G illumination of 100 mW/cm² from a 150 W Xe lamp. Conditions of solar simulation were calibrated before measurement using a Si reference cell with a KG5 filter certified by the National Institute of Advanced Industrial Science and Technology (AIST) in Japan.

### Experimental Example

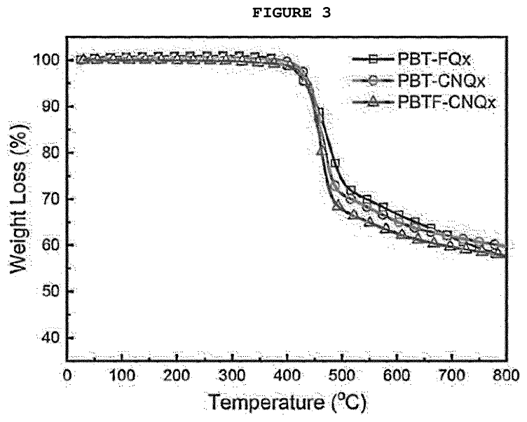

The three polymers exhibited satisfactory solubility in chloroform, tetrahydrofuran (THF), and toluene. Gel peLmeation chromatography (GPC) using a THF eluent was performed to measure a number average molecular weight of each of the polymers. The number average molecular weight values of PTB-FQx, PTB-CNQx, and PTBF-CNQx were 38.40 KDa, 59.89 KDa, and 26.08 KDa, respectively. In addition, the polymers were confirmed to have high thermal stability through thermogravimetric analysis (TGA) at a heating rate of 10° C./min under a nitrogen atmosphere, and a decomposition onset temperature at 5% weight loss was above 430° C. (See FIG. 3).

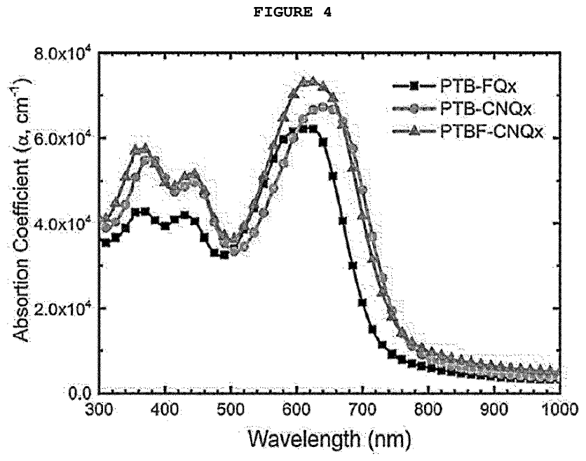

The optical properties of the polymers were examined using an UV-Vis absorption spectrum of the film. The results thereof are shown in FIG. 4. Like other D-A type polymers, all of the three polymers exhibited two different absorption regions in high-energy (in a range of 320 nm to 480 nm) and low-energy (in a range of 520 nm to 780 nm) portions of the spectrum. Peaks in a shorter wavelength region are related to p-p* transition, while peaks in a longer wavelength region correspond to ICT formation of a polymer backbone. The ICT absorption peak of PTB-CNQx was red-shifted to 642 nm, compared to that of PTB-FQx at 619 nm. Such change occurs because the CN group has a higher electron-withdrawing ability than the Fluorine atom, and the ICT formation is thus promoted. The ICT peak of PTBF-CNQx was blue-shifted to 618 nm by adding two fluorine atoms to the BDT unit.

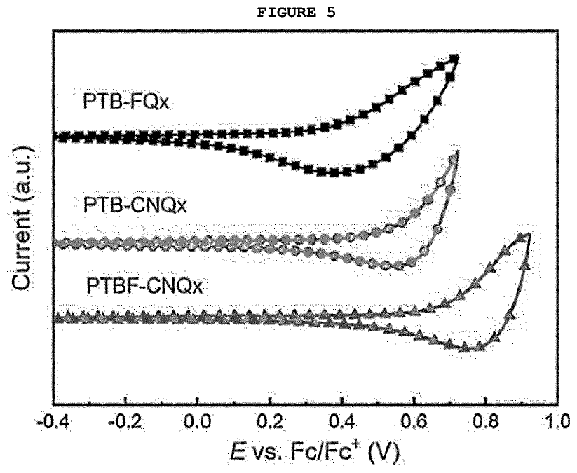

Such results may be related to an increase in band gaps of the polymers due to a decrease in a HOMO energy level. The absorption coefficients of the polymers contained in the films were 6.23×10⁴ cm⁻, 6.73×10⁴ cm⁻, and 7.32×10⁴ cm⁻¹ for PTB-FQx, PTB-CNQx, and PTBF-CNQx, respectively. The α value of the polymer was able to be increased stepwise by sequential chemical modification of the polymer, that is, CN group substitution for a fluorine atom in the electron-withdrawing Qx unit, followed by the addition of the two fluorine atoms to the electron-donating BDT unit. In addition, the optical band gaps of PTB-FQx, PTB-CNQx, and PTBF-CNQx measured using an absorption edge were 1.72 eV, 1.65 eV, and 1.67 eV, respectively. The tendency of the optical band gap values was well consistent with the change of the maximum ICT peaks of the polymers. To evaluate the HOMO energy level, the electrochemical oxidation behaviors of the polymers were examined through cyclic voltammetry measurements. As shown in FIG. 5, the oxidation onset potentials of PTB-FQx, PTB-CNQx, and PTBF-CNQx for ferrocene (Fc)/ferrocenium (Fc⁺) external standards were 0.38 V, 0.53 V, and 0.68 V, respectively. Considering the energy level of ferrocene (−4.80 eV), the HOMO levels of PTB-FQx, PTB-CNQx, and PTBF-CNQx are estimated to be −5.18 eV, −5.33 eV, and −5.48 eV, respectively. In addition, the LUMO energy levels of the polymers were determined based on the HOMO energy levels and the optical band gaps. The LUMO energy level values of PTB-FQx, PTB-CNQx, and PTBF-CNQx were −3.46 eV, −3.68 eV, and −3.81 eV, respectively. Compared to the energy level of the fluorinated reference polymer (PTB-FQx), the incorporation of the CN substituent can stabilize the LUMO energy level of PTB-CNQx (decreased by about 0.22 eV) more than the HOMO energy level of PTB-CNQx (decreased by about 0.15 eV). Therefore, the band gap of PTB-CNQx (1.65 eV) becomes smaller than that of PTB-FQx (1.72 eV). Changes in an electronic structure observed during conversion from PTB-FQx to PTB-CNQx are well consistent with those observed in other cyano group-substituted polymers. In addition, the HOMO and LUMO energy levels of PTBF-CNQx are further reduced to −5.48 eV and −3.81 eV, respectively, due to the two fluorine atoms added to the BDT unit. All data on the optical and electrochemical properties of the polymers is summarized in Table 1 below. Taken overall, the introduction of the electron-withdrawing CN group and the fluorine atoms into the Qx and BDT units, respectively, can significantly affect the optical and electrochemical properties of the polymers.

TABLE 1
Optical and electrochemical properties of
PTB-FQx, PTB-CNQx, and PTBF-CNQx

| | | | Absorption | |
|---|---|---|---|---|
| | λ_{edge}(nm)^{a} | λₘₐₓ^{film} | Coefficent | HOMO^{e}/LUMO^{f} |
| Polymer | E_{gap}^{opt}(eV)^{b} | (nm)^{c} | (cm⁻¹)^{d} | (eV) |
| PTB-FQX | 719 | (429, 619) | 6.23 × 104 | −5.18/−3.46 |
| | 1.72 | | at 619 nm | |
| PTB-CNQX | 753 | (443, 642) | 6.73 × 104 | −5.33/−3.68 |
| | 1.65 | | at 642 nm | |
| PTBE- | 743 | (441, 618) | 7.32 × 104 | −5.48/−3.81 |
| CNQX | 1.67 | | at 618 nm | |

ªAbsorption edge,
^{b}Estimate from absorption edge,
^{c}Maximum absorption wavelength of polymer film,
^{d}Absorption coefficient of polymer film,
^{e}Estimate from oxidation onset level of CV curve,
^{f}Calculated value from HOMO and optical band gap

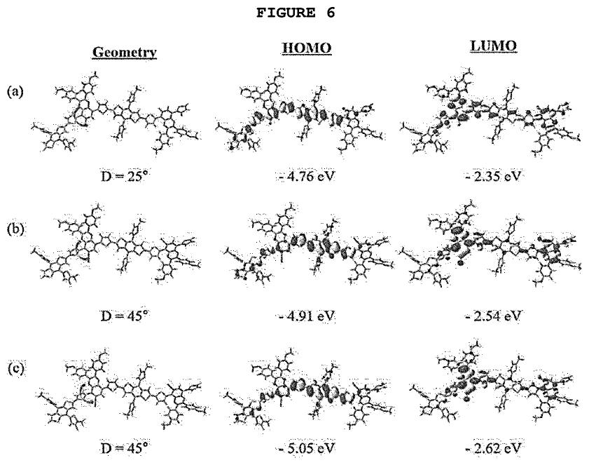

To estimate frontier molecular orbitals and optimized geometries of the polymer, computational calculations based on density-functional theory (DFT) were performed on dimer model units at B3LYP/6-31** level of the Gaussian 09 program. The results are shown in FIG. 6. For simple simulation, all alkyl and alkoxy chains in polymer structures were reduced to methyl and methoxy units, respectively. In the optimized geometry, a dihedral angle between the Qx unit and thiophene of PTB-FQx is 25°, and a sulfur (S) atom in thiophene faces opposite from a nitrogen atom in Qx. When the fluorine atom of the Qx unit was substituted with the CN group, the dihedral angles increased to 45° in PTB-CNQx and PTBF-CNQx. Due to significant steric hindrance induced by the bulky CN group, the polymer morphology may be further tilted. HOMO wave function of the polymer is delocalized along the polymer backbone. However, the replacement of the fluorine atom with the CN group can lead to further concentrated LUMO wave functions in the electron-withdrawing Qx units of PTB-CNQx and PTBF-CNQx, compared to LUMO wave function of PTB-FQx. Therefore, a significant change in the LUMO energy level of the polymer is expected in the presence of the CN substituent. The calculated HOMO energy level/LUMO energy level of PTB-FQx, PTB-CNQx, and PTBF-CNQx were −4.76 eV/−2.35 eV, −4.91 eV/−2.54 eV, and −5.05 eV/−2.62 eV, respectively. Comparing PTB-FQx and PTB-CNQx, the LUMO energy level was noticeably reduced from −2.35 eV to −2.54 eV, while the HOMO energy level was relatively slightly reduced from −4.76 eV to −4.91 eV. Due to the additional fluorine atoms introduced into the BDT unit, the LUMO and HOMO energy levels of PTBF-CNQx further decreased to −5.05 eV and −2.62 eV, respectively. Taken overall, the tendency of the LUMO and HOMO energy levels calculated using theoretical analysis was well consistent with those obtained through the optical and electrochemical experiments.

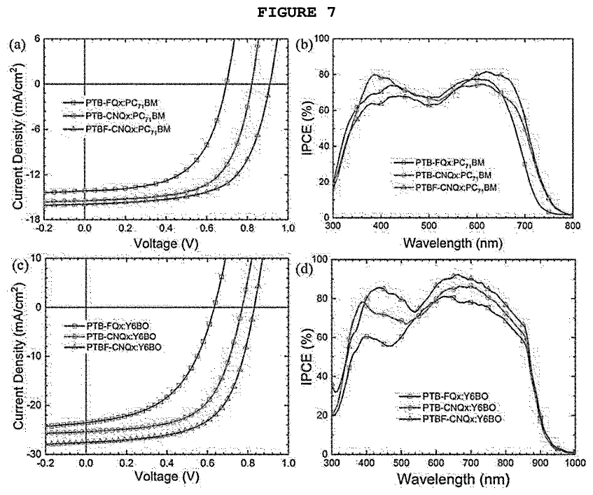

The photovoltaic properties of the polymers were studied using the inverted PSC composed of the ITO, ZnO, donor and acceptor, MoO₃, and Ag. To optimize the performance of devices containing PC₇₁BM acceptors, several devices were fabricated by varying critical parameters, such as mixing ratios of the donor and acceptor in the polymer, types and concentrations of processing additives, and thickness of the active layer, and then tested. The optimal mixing ratios of the polymer:PC₇₁BM were determined to be 3:5 for PTB-FQx and PTB-CNQx, and 3:4 for PTBF-CNQx. In addition, the thickness of the active layer was adjusted to 75 nm, and 3.0 vol. % of 1,8-diiodooactane (DIO) was added as the processing additive under optimal conditions. The J-V curve of the devices based on PC₇₁BM in the optimal condition under AM 1.5G illumination is shown in FIG. 7A. The photovoltaic parameters are listed in Table 2 below. The PCE of the device based on PTB-FQx was only 5.7%. However, the PCE of the device based on PTB-CNQx substituted with the single CN group increased to 8.0%. Such significantly improved PCE, observed from the device based on PTB-CNQx, results from the simultaneous increases of all of the device parameters, including J_{SC}, V_{OC}, and FF, compared to the device based on PTB-FQx. When replacing the fluorine atom in the Qx unit of PTB-FQx with the further strong electron-withdrawing CN group, PTB-CNQx may have improved light absorption ability and low HOMO energy level, thereby increasing the J_{SC} and V_{OC} values of the PSC. The two fluorine atoms added to the thiophene side chain of the BDT unit in PTBF-CNQx, in addition to the CN substituent, can induce similar positive effects on the molar absorption coefficient and HOMO energy level of the polymer. Thus, among the devices, the highest PCE value (9.2%) was obtained from the PTBF-CNQx-based device, which had the highest J_{SC}, V_{OC}, and FF values of 16.0 mA/cm², 0.91 V, and 63.6%, respectively. As shown in FIG. 7B, an incident photon-to-current efficiency (IPCE) curve of all of the devices exhibited satisfactory photon response with the maximum IPCE value exceeding 70% in a wavelength range of 300 nm to 700 nm. The J_{SC} values calculated using the IPCE curve were well consistent with the values obtained based on the J-V curve (see Table 2).

TABLE 2
Best photovoltaic parameters for each PSC with
PC₇₁BM acceptor or Y6BO acceptor (average of photovoltaic
parameters for each device (average of ten devices) is
indicated in parentheses)

| | | | J_{sc} | | | | J_{sc,cal}^{d} |
|---|---|---|---|---|---|---|---|
| | | Blend | (mA/ | V_{oc} | FF | PCE | (mA/ |
| Polymer | Acceptor | Ratio^{a} | cm²) | (V) | (%) | (%) | cm²) |
| PTB-FQx | PC₇₁BM | 3:5^{b} | 14.2 | 0.70 | 57.0 | 5.7 | 14.5 |
| | | | (14.1) | (0.70) | (56.8) | (5.6) | |
| PTB-CNQx | PC₇₁BM | 3:5^{b} | 15.9 | 0.82 | 63.3 | 8.0 | 15.3 |
| | | | (15.2) | (0.82) | (62.5) | (7.8) | |
| PTBF-CNQx | PC₇₁BM | 3:4^{b} | 16.0 | 0.91 | 63.6 | 9.2 | 15.6 |
| | | | (15.9) | (0.91) | (62.3) | (9.0) | |
| PTB-FQx | Y6BO | 3:3^{c} | 23.5 | 0.63 | 50.2 | 7.4 | 22.8 |
| | | | (22.9) | (0,63) | (49.4) | (7.1) | |
| PTB-CNQx | Y6BO | 3:3^{c} | 25.4 | 0.77 | 60.0 | 11.7 | 24.6 |
| | | | (25.2) | (0.77) | (59.6) | (11.6) | |
| PTBF-CNQx | Y6BO | 3:3^{c} | 27.6 | 0.83 | 61.2 | 14.0 | 26.6 |
| | | | (27.4) | (0.83) | (61.0) | (13.9) | |

^{a}Mass ratio of polymer to acceptor,
^{b}3.0 vol. % of 1,8-diiodooctane added as process additive,
^{c}0.5 vol. % of 1,8-diiodooctane added as process additive,
^{d}calculated from IPCE curve

In addition, similar inverted PSCs were fabricated using non-fullerene acceptors and tested. Y6BO, a well-known non-fullerene acceptor, enhances intermolecular interactions through polymer donors as well as complementary optical absorption in a long-wavelength region in a range of 600 nm to 900 nm, thereby improving photovoltaic performance of the PSCs. The photovoltaic properties of the PSCs were screened under various fabrication conditions. Then, the best device performance was realized at a polymer:Y6BO mixing ratio of 1:1 (w/w). In addition, an active layer thickness of the optimal device was controlled to be in a range of 85 nm to 90 nm using 0.5 vol. % of DIO. The J-V curve of the devices containing Y6BO in the optimal condition under AM 1.5G illumination is shown in FIG. 7C. The measurement results of the photovoltaic performance are listed in Table 2 below. The PCEs of the devices containing Y6BO were mostly much higher than those of the devices containing PC71BM. For example, the PCE of the PC₇₁BM-based devices containing PTB-FQx was 5.7%, while the PCE of the Y6BO-based devices increased to 7.4%. In addition, the devices containing PTB-CNQx and PTBF-CNQx exhibited similar PCE enhancement even when the acceptor PC₇₁BM was replaced with Y6BO (see Table 2). Such enhancement in the PCE of the Y6BO-based devices is mainly due to significant photocurrent generation. The extensive complementary optical absorption between the donor polymer and Y6BO in the active layer can significantly increase the J_{SC} value of the device. As shown in FIG. 7D, with the maximum values exceeding 80%, the IPCE curve of all of the devices covers a wide wavelength in a range of 350 nm to 900 nm, and the J_{SC} values of all of the devices increase to be 23.5 mA/cm² or higher. In addition, similar to the PCE tendencies in the PC₇₁BM-based devices, the PCE of the device containing the Y6BO acceptor gradually improved in the order of PTB-FQx, PTB-CNQx, and PTBF-CNQx. In a step-by-step modification process of the polymer structure, J_{SC}, V_{OC}, and FF gradually increased. As a result, the device based on PTBF-CNQx, which had J_{SC}, V_{OC}, and FF of 27.6 mA/cm², 0.83 V, and 61.2%, respectively, achieved the highest PCE of 14.0%. To examine the charge generation properties of the Y6BO-based device, photoluminescence (PL) spectra of the blend films containing the donor polymer and Y6BO were analyzed. As seen in FIG. 8, all of the polymers exhibited broad PL emission in the range of 670 nm to 870 nm at an excitation wavelength of 610 nm. However, the PL emission of all of the Y6BO-containing blend films was mostly quenched, indicating that efficient charge generation was realized on an interface between the polymer and Y6BO.

As a result, when synthesizing the donor polymer in Example of the present invention, it was confirmed that the D-A type Qx-based polymer obtained by the sequential synthesis strategy of replacing the fluorine atom with the CN group in the A unit of the reference polymer and adding fluorine atoms to the D unit was significantly useful in enhancing the PCE of the device regardless of the type of acceptor being used.

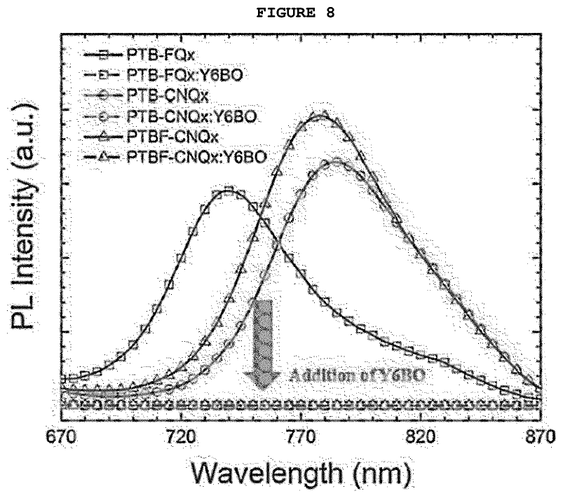

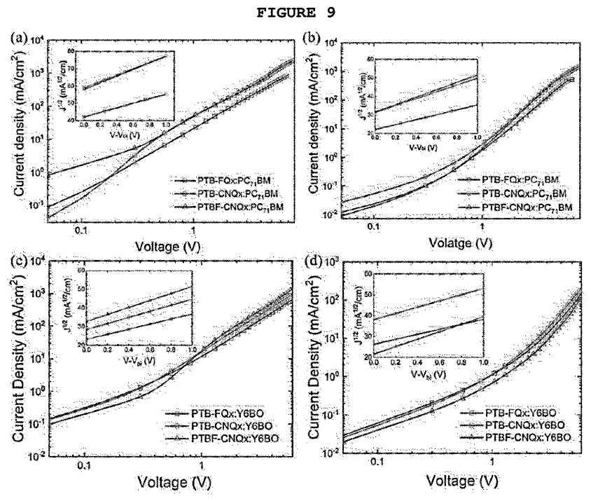

Charge transfer properties of the devices were examined by preparing a hole-only device formed of ITO, PEDOT and PSS, the polymer and the acceptor (PC₇₁BM or Y6BO), and Au (50 nm) and an electron-only device formed of ITO, ZnO (25 nm), the polymer and the acceptor (PC₇₁BM or Y6BO), and Al (50 nm). As expected, the hole-only device and the electron-only device containing the PC₇₁BM or Y6BO acceptor exhibited the characteristics of space-charge-limited current behavior. The characteristics can be represented by using the famous Mott-Gurney law (FIG. 9). The calculated hole mobilities/electron mobilities for PTB-FQx, PTB-CNQx, and PTBF-CNQx with the PC₇₁BM acceptor were 1.89×10⁻³ cm²V⁻¹s⁻¹/1.90×10⁻³ cm²V⁻¹s⁻¹, 3.64×10⁻³ cm²V⁻¹s⁻¹/3.71×10⁻³ cm²V⁻¹s⁻¹, and 4.01×10⁻³ cm²V⁻¹s⁻¹/4.32×10⁻³ cm²V⁻¹s⁻¹, respectively. Both of the hole mobility and the electron mobility were simultaneously and gradually improved in the order of PTB-FQx, PTB-CNQx, and PTBF-CNQx, showing satisfactory correlation with the J_{SC} and FF tendencies of the devices containing each of the polymers. The hole mobilities/ electron mobilities for the polymers containing the Y6BO acceptors also increased in the same order, in which the hole mobility/ electron mobility values of PTB-FQx, PTB-CNQx, and PTBF-CNQx were 2.92×10⁻³ cm²V⁻¹s⁻¹/2.29×10⁻³ cm²V⁻¹s⁻¹, 4.19×10⁻³ cm²V⁻¹s⁻¹/3.54×10⁻³ cm²V⁻¹s⁻¹, and 6.59×10⁻³ cm²V⁻¹s⁻¹/6.02×10⁻³ cm²V⁻¹s⁻¹, respectively. The tendency of the Y6BO-based devices, which exhibited higher hole mobility and electron mobility than the PC₇₁BM-based devices, was consistent with the tendency of each of the J_{SC} values.

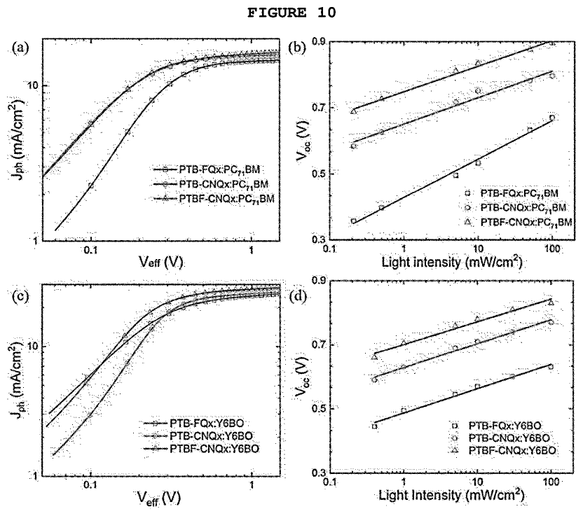

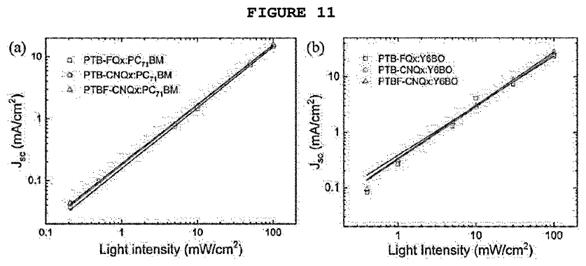

To obtain additional information on the photovoltaic properties of the polymers, the relation between photocurrent density (J_{Ph}) and effective voltage (V_{eff}) of the devices containing the PC₇₁BM acceptors was examined (where J_{Ph}=J_{L} (current density under illumination)−J_{D} (current density under dark condition) and V_{eff}=V₀ (voltage at J_{Ph}=0)−Vₐ (applied voltage)). As shown in FIG. 10E, in the saturation photocurrent region (V_{Sat}), the V_{eff} values of the devices increases in the order of PTB-FQx, PTB-CNQx, and PTBF-CNQx. A lower V_{Sat} indicates a faster transition from a space-charge-limited region to a saturation region. The V_{Sat} values of the polymer-containing devices followed the similar tendencies of the J_{SC} and PCE values. In addition, exciton dissociation probabilities (J_{Ph}/J_{Sat}) were calculated, and the values thereof for the devices based on PTB-FQx, PTB-CNQx, and PTBF-CNQx were 85.4%, 91.0%, and 91.2%, respectively. Such results indicate that the device based on PTBF-CNQx exhibited the best charge-extraction behavior. In addition, a maximum exciton generation rate (G_{MAX}) at J_{Sat} of the device was estimated using the equation of G_{MAX}=J_{Ph}/q·L, where q and L represented an electronic charge and a thickness of the active layer, respectively. The G_{MAX} values at J_{Sat} of the devices based on PTB-FQx, PTB-CNQx, and PTBF-CNQx, were 1.27×10²⁸, 1.38×10²⁸, and 1.42×10²⁸, respectively. The tendency of the G_{MAX} values of the devices is well consistent with the tendency of the absorption coefficient of the polymer due to the strong dependence of Graz on the optical absorption of the active layer. In addition, the relation between V_{OC} and light intensity, defined as V_{OC}=(nkT/q)×ln(light intensity), was monitored (see FIG. 10B). Here, k, T, and q indicate the Boltzmann constant, an absolute temperature, and an elementary charge, respectively. The value of n approaches 1 when bimolecular recombination is dominant and reaches 2 when trap-assisted recombination is dominant. The n values for the devices based on PTB-FQx, PTB-CNQx, and PTBF-CNQx were calculated to be 1.97, 1.35, and 1.30, respectively. Thus, the lowest trap-assisted recombination of the device based on PTBF-CNQx underlies the highest J_{SC} and FF values. In addition, charge carrier recombination properties of the device were examined using the relation between J_{SC} and light intensity, defined as J_{SC}=(light intensity)^{α}. As shown in FIG. 11A, the α values of the devices based on PTB-FQx, PTB-CNQx, and PTBF-CNQx were 0.98, 0.97, and 0.96, respectively, indicating that undesirable bimolecular recombination was effective inhibited. Overall, it was seen that most of the device parameters related to the exciton generation, charge extraction, and charge recombination properties of the PC71BM-containing devices were continuously improved by sequentially modifying the polymer structure. Such results strongly support the tendencies observed in J_{SC}, FF, and PCE of the PSCs based on the PC₇₁BM acceptor.

The charge generation, charge extraction, and charge recombination properties of the device based on the Y6BO acceptor were also examined using the same device structure. As can be seen in FIG. 10C, the V_{eff} of the PSCs based on Y6BO at V_{Sat} improved in the order of PTB-FQx, PTB-CNQx, and PTBF-CNQx, which had J_{Ph}/J_{Sat} values of 87.2%, 93.7%, and 93.3%, respectively. Through such results, the J_{SC} and PCE of the devices containing the CN group-substituted polymers higher than that of the devices containing fluorinated PTB-FQx can be explained. The G_{MAX} values under J_{Sat} condition of the Y6BO-based devices using PTB-FQx, PTB-CNQx, and PTBF-CNQx were 1.98×10²⁸, 1.99×10²⁸, and 2.05×10²⁸, respectively. The G_{MAX} data for the Y6BO-containing devices is proportional to the absorption coefficient of the polymer. The same tendency was observed in the Graz data for the PC₇₁BM-based devices. In addition, using the relation between V_{OC} and the light intensity, the n values of the Y6BO-based PSCs using PTB-FQx, PTB-CNQx, and PTBF-CNQx were estimated to be 1.28, 1.27, and 1.20, respectively (see FIG. 10D). In particular, the n values of the Y6BO-containing devices were lower than those of the PC₇₁BM-containing devices due to less trap-assisted recombination. In addition, the α values of the devices based on PTB-FQx, PTB-CNQx, and PTBF-CNQx were calculated to be 0.95, and 0.96, respectively, using the relation between J_{SC} and light intensity. Thus, the Y6BO-containing devices appeared to perform a further dominant monomolecular recombination process (see FIG. 11B). Like the devices based on PC₇₁BM, the exciton generation, charge extraction, and charge recombination properties of the devices based on the Y6BO acceptor gradually improved in the order of PTB-FQx, PTB-CNQx, and PTBF-CNQx.

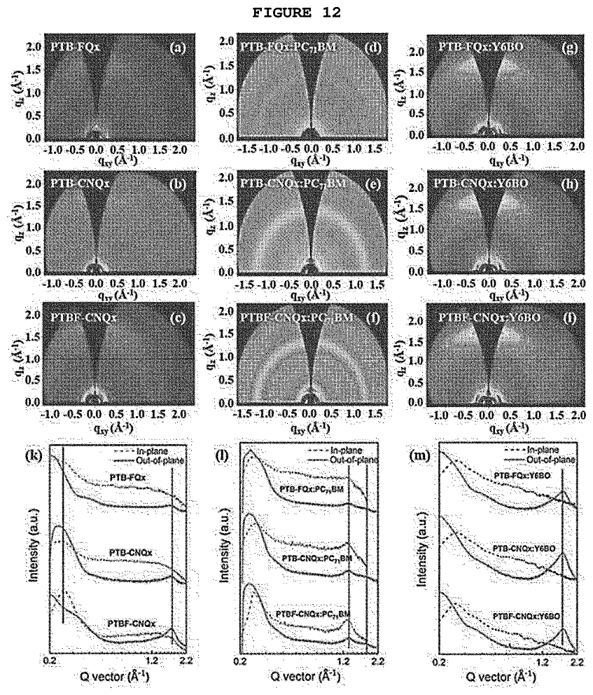

Molecular ordering and crystallinity of the active layer in the device are important in determining the overall photovoltaic performance of the PSC. Therefore, grazing-incidence wide-angle X-ray scattering (GIWAXS) measurements were performed on the polymer films and the blend films containing the PC₇₁BM or Y6BO acceptor. The resulting images and plots are shown in FIG. 12. As observed in GIWAXS patterns (see FIGS. 12A to 12C) and associated scattering profiles in an in-plane (IP) direction and an out-of-plane (OOP) direction (see FIG. 12K), the intensity of the (100) peak along the IP direction and that of the (010) peak in OOP direction gradually increased in the order of PTB-FQx, PTB-CNQx, and PTBF-CNQx. In addition, in the polymer films based on PTB-FQx, PTB-CNQx, and PTBF-CNQx, the p-p stacking diffraction (010) peaks are located at 1.65 Å⁻¹, 1.67 Å⁻¹, and 1.70 Å⁻¹, respectively, along the OOP direction, and p-p stacking distances correspond to 3.85, 3.80, and 3.69 Å, respectively. Such results mean that the Qx and BDT units of the polymer structure have a face-on orientation as the electron-withdrawing CN and F moiety are successively added thereto, respectively. The face-on orientation with a shorter p-p stacking distance in a crystalline domain can facilitate vertical charge transfer in the active layer, thereby improving the photovoltaic properties of the PSCs. However, the diffraction peak intensities corresponding to the peaks in the OOP direction (010) of the blend films containing PC71BM and each of the polymers were considerably weaker than those of the polymer films (see FIGS. 12D to 12F). The peak at about 1.30 Å⁻¹ in the IP and OOP directions of such blend films (see FIG. 12K) originates from an amorphous PC₇₁BM domain.

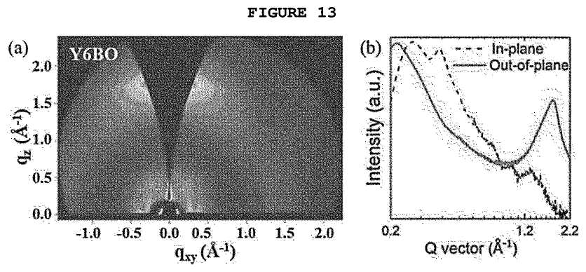

Interestingly, the p-p stacking peaks along the IP and OOP directions and the scattering patterns in lamellas were reconstructed for the blend films containing each of the polymers and Y6BO (see FIGS. 12G to 12I). In the Y6BO blend polymer film, the peaks along the IP direction (100) and the peak intensities along the OOP direction (010) are much more noticeable than the corresponding peaks in the polymer films. Such enhanced peak intensity may be attributed to the apparent face-on molar packing orientation of the Y6BO acceptor (see FIG. 13). However, the favorable face-on orientation can be foinued due to strong intermolecular interactions between the polymers and Y6BO in the blend films. Therefore, J_{SC}, FF, and PCE can be improved by greatly enhancing the charge transfer properties of the devices including the polymers and Y6BO. In addition, such results support that the devices containing the Y6BO acceptors exhibited better photovoltaic performance than that the devices containing the PC₇₁BM acceptors.

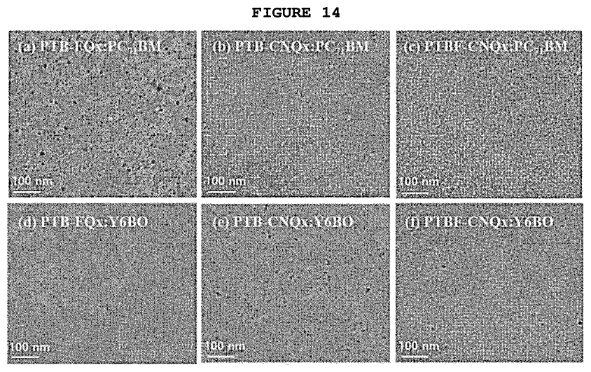

The morphologies of the blend films each independently based on the polymer and PC₇₁BM and the polymer and Y6BO, with optimal processing conditions, were examined by transmission electron microscopy (see FIG. 14). Significant phase separation and aggregation were observed for the active layers based on PTB-FQx with PC71BM or Y6BO. However, the active layers based on PTB-CNQx exhibited better nanoscale phase separation and bicontinuous interpenetrating network, and the active layer based on PTBF-CNQx exhibited the best nanoscale phase separation morphology. Therefore, favorable nanoscale phase separation in the active layer can increase the PCE of the related PSCs through efficient charge separation and charge transfer. In addition, a phase separation size of the active layer based on the blending of the polymer and Y6BO is slightly larger than that of the active layer based on the corresponding polymer and PC₇₁BM. Such results are consistent with the fact that the FF of the Y6BO-based device is lower than that of the PanBM-based device.

The present invention is not limited to the above embodiments, but can be manufactured in a variety of different foLms. Those skilled in the art to which the present invention pertains will understand that other specific forms can be implemented without changing the technical spirit or essential features of the present invention. Therefore, it should be understood that the aforementioned embodiments are given by way of illustration only, and are not intended to be limiting in all aspects.

### INDUSTRIAL APPLICABILITY

According to the present invention, a conjugated polymer for a polymer solar cell donor is provided a D-A form in which an electron-donating unit (benzodithiophene, BDT) and an electron-withdrawing unit (quinoxaline, Qx) are combined, while a cyano (CN) substituent is introduced into the Qx unit instead of fluorine (F) to improve charge generation, charge transfer, and charge recombination properties of the polymer solar cell, regardless of types of acceptor included in a photoactive layer. As a result, a polymer solar cell with greatly improved photoelectric conversion efficiency (PCE) can be implemented. In particular, when the conjugated polymer for the donor containlng the ON group in the Qx unit further contains two fluorine (F) atoms in a thiophene side chain of the EDT unit, photovoltaic performance is further improved. Therefore, the polymer solar cell exhibiting a significantly high photo-conversion efficiency of up to 14% can be implemented.

1. A conjugated polymer compound for a polymer solar cell donor, the compound represented by Formula 1: 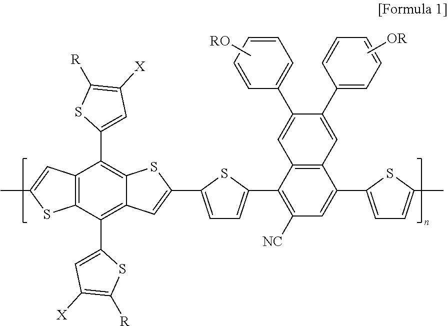
(In Formula 1,
n is an integer of 2 or more,
R is a substituted or unsubstituted alkyl having 2 to 10 carbon atoms, and
X is H or F)

2. The compound of claim 1, represented by Formula 2:

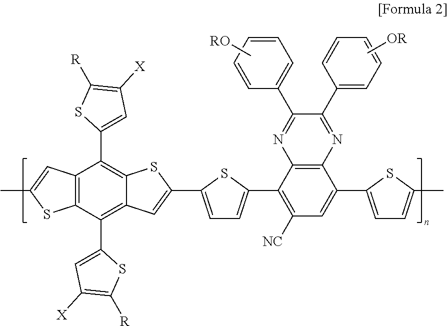

3. The compound of claim 1, represented by Formula 3:

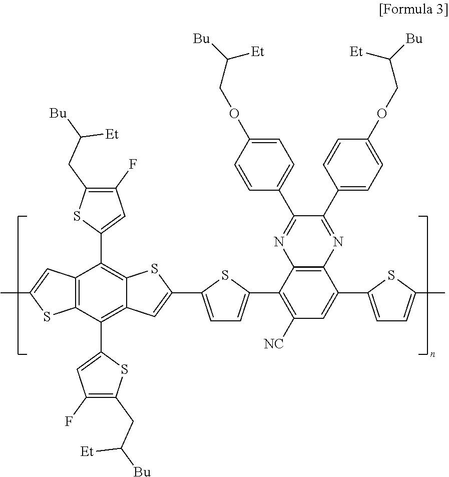

4. The compound of claim 1, represented by Formula 4:

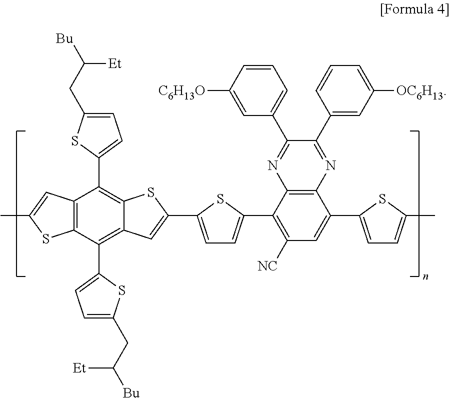

5. A polymer solar cell comprising a photoactive layer in which the compound of claim 1 is comprised as a donor.

6. The polymer solar cell of claim 5, having an inverted structure constructed by sequentially stacking:
an ITO substrate;
a photoactive layer comprising an acceptor and the donor made of the compound represented by any one of Formulas 1 to 4;
a metal oxide layer comprising molybdenum oxide (MoO₃); and
a silver (Ag) electrode layer.

7. The polymer solar cell of claim 6, wherein the acceptor is made of [6,6]-Phenyl C71 butyric acid methyl ester (PC71BM)) or 2,2′-((2Z,2′Z)-((12,13-bis(2-butyloctyl)-12,13-dihydro-[1,2,5]thiadiazolo[3,4-e]thieno[2″,3″:4′,5]thieno[2′,3′:4,5]pyrrolo[3,2-g]thieno[2′,3′:4,5]thieno[3,2-b]indole-2,10-diyl))bis(methanylylidene))bis(5,6-difluoro-3-oxo-2,3-dihydro-1H-indene-2,1- diylidene))dimalononitrile (Y6BO).

8. The polymer solar cell of claim 6, further comprising a zinc oxide (ZnO) layer between the ITO substrate and the photoactive layer.
